(19) United States
(12) Patent Application Publication
(10) Pub. No.: US 2023/0303457 A1
(43) Pub. Date: Sep. 28, 2023

(54) JOINED BODY, HOLDING DEVICE, AND ELECTROSTATIC CHUCK

(71) Applicant: NGK SPARK PLUG CO., LTD., Nagoya-shi, Aichi (JP)

(72) Inventors: Osamu YOSHIMOTO, Nagoya-shi (JP); Ryuichi ARAKAWA, Nagoya-shi (JP); Tomoo TANAKA, Nagoya-shi (JP)

(21) Appl. No.: 18/041,284

(22) PCT Filed: Jun. 25, 2021
(86) PCT No.: PCT/JP2021/024111

§ 371 Date: Feb. 10, 2023

(30) Foreign Application Priority Data
Aug. 21, 2020 (JP) 2020-139760

(51) Int. Cl. C04B 37/02; H01L 21/683

(52) U.S. Cl. CPC C04B 37/026; H01L 21/6831; C04B 2237/597; C04B 2237/62

(57) ABSTRACT

A joined body includes a first member and a second member which are joined together via a joining portion including a metal layer having a plurality of pores communicating with each other. The first member and the metal layer have respective through holes formed in the first member and the metal layer, respectively, and communicating with each other. A tubular member is disposed between an inner side portion of the through hole formed in the metal layer and an interior portion of the metal layer.

### BACKGROUND OF THE INVENTION

### 1. Field of the Invention

The present invention relates to a joined body, a holding apparatus, and an electrostatic chuck.

### 2. Description of Related Art

Heretofore, a joined body in which two members are joined together has been known. In general, a holding apparatus for holding a wafer has a joined body which includes a ceramic member having a placement surface on which the wafer is placed, a metal member for cooling the wafer, and a joining portion for joining the ceramic member and the metal member (see, for example, Patent Document 1).

[Patent Document 1] Japanese Patent No. 3485390

### BRIEF SUMMARY OF THE INVENTION

In some cases, a metal layer is disposed in the joining portion of the joined body in order to relax stresses generated due to the difference in thermal expansion between the ceramic member and the metal member. When a through hole through which a fluid flows is formed in the metal layer, there arises a possibility that the fluid in the through hole leaks from an inner side portion of the through hole to an interior portion of the metal layer, or a fluid present outside the holding apparatus flows into the through hole through pores of the metal layer. Also, a fragment of the metal layer or the like may fall into the through hole.

An object of the present invention is to provide a technique for a joined body including a metal layer having a through hole formed therein, the technique preventing falling of a fragment of the metal layer into the through hole while restricting movement of fluids between an inner side portion of the through hole and an interior portion of the metal layer.

The present invention has been accomplished so as to solve at least part of the above-described problem and can be realized in the following aspects.

According to one aspect of the present invention, there is provided a joined body in which a first member and a second member are joined together via a joining portion including a metal layer having a plurality of pores communicating with each other. In this joined body, the first member and the metal layer have respective through holes formed in the first member and the metal layer that communicate with each other, and a tubular member is disposed between an inner side portion of the through hole formed in the metal layer and an interior portion of the metal layer.

According to this configuration, the metal layer contained in the joining portion has a plurality of pores communicating with each other, and a through hole which communicates with the through hole formed in the first member is formed in the metal layer. A tubular member is disposed between an inner side portion of the through hole formed in the metal layer and an interior portion of the metal layer. As a result, when a fluid flows through the inner side portion of the through hole, the tubular member can prevent the fluid from leaking to an interior portion of the metal layer. Also, the tubular member hinders a fluid from flowing into the inner side portion of the through hole from the plurality of pores of the metal layer, thereby preventing the fluid present outside the through hole from flowing into the through hole. Also, the tubular member can prevent a fragment of the metal layer, etc., from falling into the through hole.

In the joined body of the above-described aspect, a through hole communicating with the through holes formed in the first member and the metal layer, respectively, may be formed in the second member. According to this configuration, the through holes formed in the first member and the metal layer, respectively, communicate with the through hole formed in the second member. In the through hole formed in the metal layer, the tubular member prevents a fluid present in the through hole from leaking into the metal layer and prevents a fluid present in the metal layer from flowing into the through hole. Therefore, a change in the flow rate of the fluid flowing through the through hole of the second member relative to the flow rate of the fluid flowing through the through hole of the first member becomes small. As a result, the fluid can be stably supplied from the first member side to the second member side, or from the second member side to the first member side, through the joined body.

In the joined body of the above-described aspect, one end portion of the tubular member may be disposed in the through hole formed in the first member, and the other end portion of the tubular member may be disposed in the through hole formed in the second member. According to this configuration, one end portion of the tubular member is disposed in the through hole of the first member, and the other end portion of the tubular member is disposed in the through hole of the second member. As a result, it is possible to prevent separation of the tubular member from the first member or the second member, which separation would otherwise occur due to thermal stress generated when the first member and the second member are joined together by the joining portion or when the joined body is used at high temperature. Therefore, it is possible to further reliably prevent falling of a fragment of the metal layer into the through hole, while further restricting movement of the fluid between the inner side portion of the through hole and the interior portion of the metal layer.

In the joined body of the above-described aspect, a bellows portion may be formed along a circumference of the tubular member to extend in a circumferential direction. According to this configuration, a bellows portion is formed along the circumference of the tubular member to extend in the circumferential direction. As a result, for example, in the case where the first member and the second member are formed of materials having different coefficients of thermal expansion, when the first member and the second member are joined together or when the joined body is used at high temperature, the bellows portion deforms in accordance with the magnitude of stress generated due to the difference in thermal expansion. When the bellows portion deforms, it is possible relax the residual stress at the junction interface between the first member and the second member and the residual stress in a member which is relatively weak against stress. Accordingly, breakage of the joined body can be prevented.

In the joined body of the above-described aspect, the tubular member may be formed of the same material as the metal layer. According to this configuration, the tubular member is formed of the same material as the metal layer. As result, the joining portion is formed of two types of materials; i.e., the material of the tubular member and the metal layer and the material of a brazing filler metal. Therefore, the composition of the joining portion becomes uniform throughout the joining portion as compared with the case where the tubular member, the metal layer, and the brazing filler metal are formed of different materials. Accordingly, local differences in thermal stress become less likely to be produced in the joining portion, thereby further reliably preventing breakage of the joined body.

In the joined body of the above-described aspect, the tubular member may have a circular cross section taken perpendicular to an axial direction of the tubular member. According to this configuration, the tubular member is formed such that its cross section perpendicular to the axial direction becomes circular. As a result, the tubular member becomes less likely to deform due to forces acting from directions intersecting the axis. Therefore, it is possible to further reliably prevent movement of fluids between the through hole and the metal layer and falling of a fragment of the metal layer into the through hole.

According to another aspect of the present invention, a holding apparatus is provided. This holding apparatus includes the above-described joined body, and the second member has a placement surface on which an object to be held is placed. According to this configuration, for example, in the case where the through holes formed in the first member and the metal layer, respectively, communicate with the through hole of the second member, a change in the flow rate of the fluid flowing through these through holes can be suppressed. Therefore, the fluid can be stably supplied between the object to be held and the placement surface. Also, since falling of a fragment of the metal layer into the through hole is prevented, contamination of the to-be-held object by the fragment of the metal layer can be prevented. As a result, the yield of products can be improved.

According to still another aspect of the present invention, an electrostatic chuck is provided. This electrostatic chuck includes the above-described holding apparatus, and the second member has an electrostatic attraction electrode disposed therein. According to this configuration, a through hole for supplying a fluid to the placement surface is formed in the joined body. In the above-described holding apparatus, clogging of the through hole due to leakage of a joining material into the through hole can be prevented by the tubular member disposed between the inner side portion of the through hole of the metal layer and the interior portion of the metal layer. As a result, falling of a fragment of the metal layer into the through hole is prevented, and therefore, contamination by the fragment of the metal layer can be prevented. Accordingly, the yield of products manufactured by using the electrostatic chuck can be improved.

Notably, the present invention can be realized in various modes. For example, the present invention may be realized as an apparatus containing the joined body, a method for manufacturing the joined body and the holding apparatus, etc.

### BRIEF DESCRIPTION OF THE DRAWINGS

FIG. 1 is a perspective view showing the appearance of an electrostatic chuck of a first embodiment.

FIG. 2 is an overall sectional view of the electrostatic chuck.

FIG. 3 is a partial sectional view of the electrostatic chuck.

FIG. 4 is a first view used for describing a tubular member.

FIG. 5 is a second view used for describing the tubular member.

FIG. 6 is a sectional view of an electrostatic chuck of a comparative example.

FIG. 7 is a sectional view of an electrostatic chuck of a second embodiment.

FIG. 8 is an enlarged sectional view of the electrostatic chuck.

FIG. 9 is a sectional view of an electrostatic chuck of a third embodiment.

FIG. 10 is an enlarged sectional view of the electrostatic chuck.

FIG. 11 is a sectional view of a modification of the electrostatic chuck of the third embodiment.

### DETAILED DESCRIPTION OF EXEMPLARY EMBODIMENTS OF THE INVENTION

### 1. First Embodiment

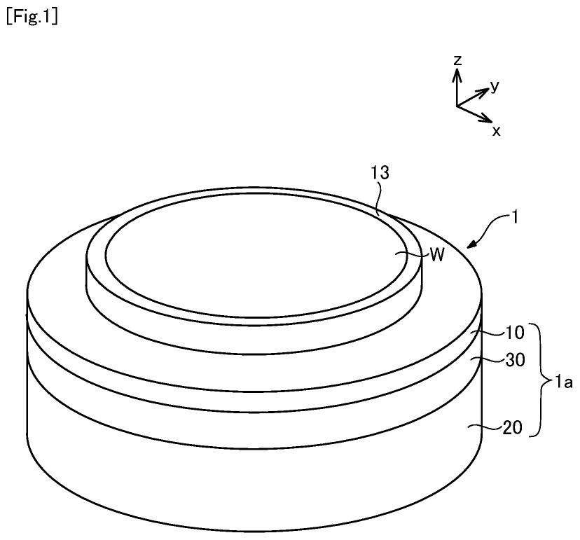

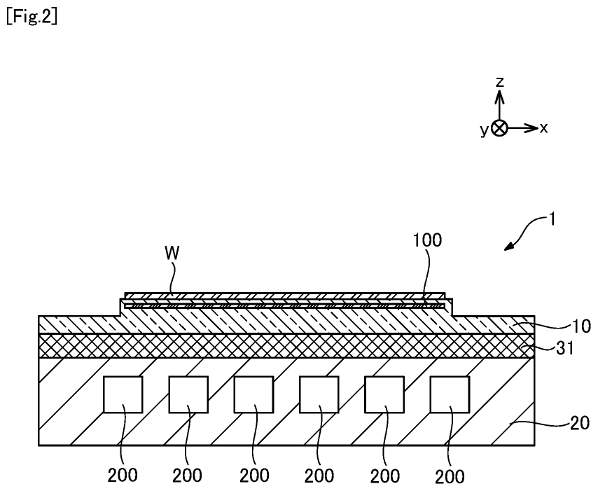

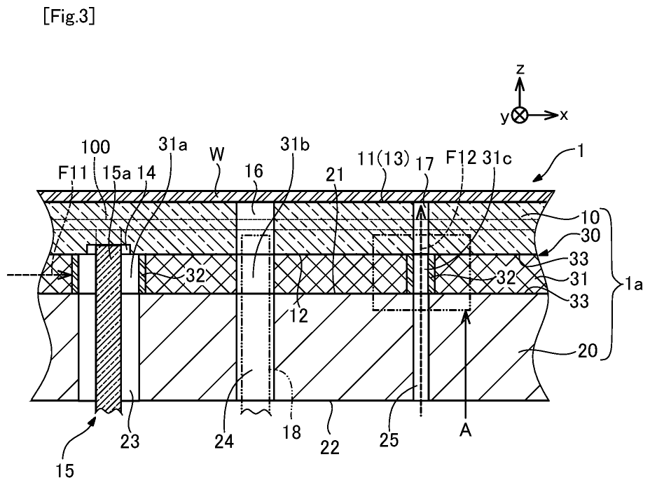

FIG. 1 is a perspective view showing the appearance of an electrostatic chuck 1 of a first embodiment. FIG. 2 is an overall sectional view of the electrostatic chuck 1. FIG. 3 is a partial sectional view of the electrostatic chuck 1. The electrostatic chuck 1 of the first embodiment is a holding apparatus which attracts a wafer W by electrostatic attraction force, thereby holding the wafer W. The electrostatic chuck 1 is provided in, for example, an etching apparatus. The electrostatic chuck 1 includes a ceramic member 10, an electrode terminal 15, a lift pin 18, a metal member 20, and a joining portion 30. In the electrostatic chuck 1, the ceramic member 10, the joining portion 30, and the metal member 20 are stacked in this order in the Z-axis direction (vertical direction). In the electrostatic chuck 1, a joined body la composed of the ceramic member 10, the joining portion 30, and the metal member 20 is an approximately circular columnar body. The ceramic member 10 corresponds to the “second member” in the claims, and the metal member 20 corresponds to the “first member” in the claims. The wafer W corresponds to the “object to be held” in the claims.

The ceramic member 10 is an approximately circular, plate-shaped member and is formed of alumina (Al₂O₃). The diameter of the ceramic member 10 is, for example, about 50 mm to 500 mm (generally, about 200 mm to 350 mm), and the thickness of the ceramic member 10 is, for example, about 1 mm to 10 mm. The ceramic member 10 has a pair of main faces 11 and 12. A placement surface 13 on which the wafer W is placed is formed on the main face 11, which is one of the pair of main faces 11 and 12. The wafer W, which is placed on the placement surface 13, is attracted and fixed to the placement surface 13 by an electrostatic attraction force generated by an electrostatic attraction electrode 100 (see FIGS. 2 and 3) disposed in the ceramic member 10. A recess 14 is formed on the other main face 12. An end portion 15a of an electrode terminal 15 for supplying electric power from an unillustrated power supply to the electrostatic attraction electrode 100 is disposed in the recess 14. Notably, the ceramic material used to form the ceramic member 10 may be aluminum nitride (AlN), zirconia (ZrO₂), silicon nitride (Si₃N₄), silicon carbide (SiC), yttria (Y₂O₃), or the like.

Two through holes 16 and 17 are formed in the ceramic member 10. The through hole 16 extends through the ceramic member 10 in the Z-axis direction, and a lift pin 18 is inserted into the through hole 16. The through hole 17 serves as a flow passage through which helium gas to be supplied between the placement surface 13 and the wafer W flows when the wafer W is placed on the placement surface 13.

The metal member 20 is a plate-shaped member having an approximately circular planar shape and is formed of stainless steel. The metal member 20 has a pair of main faces 21 and 22. The diameter of the metal member 20 is, for example, about 220 mm to 550 mm (generally, about 220 mm to 350 mm), and the thickness of the metal member 20 is, for example, about 20 mm to 40 mm. A coolant passage 200 is formed in the metal member 20 (see FIG. 2). When a coolant (for example, fluorine-based inert liquid, water, or the like) is supplied to the coolant passage 200, the ceramic member 10 is cooled via the joining portion 30, whereby the wafer W placed on the ceramic member 10 is cooled. Notably, the type of the metal used to form the metal member 20 may be copper (Cu), aluminum (Al), aluminum alloy, titanium (Ti), titanium alloy, or the like.

Three through holes 23, 24, and 25 are formed in the metal member 20. As shown in FIG. 3, each of the three through holes 23, 24, and 25 extends through the ceramic member 10 in the z-axis direction. The electrode terminal 15 is inserted into the through hole 23. The lift pin 18 is inserted into the through hole 24. The through hole 25 serves as a flow passage through which helium gas to be supplied between the placement surface 13 and the wafer W flows when the wafer W is placed on the placement surface 13.

The joining portion 30 includes a metal layer 31, tubular members 32, and a brazing filler metal 33 and joins the ceramic member 10 and the metal member 20 together. The metal layer 31 is a plate-shaped member having an approximately circular planar shape. The metal layer 31 is a porous body having a plurality of pores communicating with each other. In the present embodiment, the metal layer 31 is a piece of felt formed from metal fibers containing titanium (Ti) and is disposed between the ceramic member 10 and the metal member 20. Notably, the metal layer 31 is not limited to the piece of felt formed from metal fibers and may be a porous material or a structural mesh material. Also, the metal used to form the metal layer 31 may be nickel (Ni), aluminum, copper, brass, an alloy of these metals, or stainless steel.

Three through holes 31a, 31b, and 31c are formed in the metal layer 31. The through hole 31a establishes communication between the recess 14 of the ceramic member 10 and the through hole 23 of the metal member 20. The through hole 31b establishes communication between the through hole 16 of the ceramic member 10 and the through hole 24 of the metal member 20. The through hole 31c establishes communication between the through hole 17 of the ceramic member 10 and the through hole 25 of the metal member 20. Namely, the through holes 23 and 31a which communicate with each other and the through holes 25 and 31c which communicate with each other are formed in the metal member 20 and the metal layer 31, respectively. The through hole 17, which communicates with the through holes 25 and 31c formed in the metal member 20 and the metal layer 31, respectively, is formed in the ceramic member 10.

Each of the tubular members 32 is a cylindrical member which is open upward and downward and has a sealed side wall. As shown in FIG. 3, the tubular members 32 are disposed in the through hole 31a and the through hole 31c, respectively. In the present embodiment, the tubular members 32 are formed of a titanium-containing metal, which is the same material as the metal layer 31, and are suitable for use under a high temperature environment. In the present embodiment, each tubular member 32 has a height of 0.5 mm to 2.0 mm and a wall thickness of 0.01 mm to 0.15 mm.

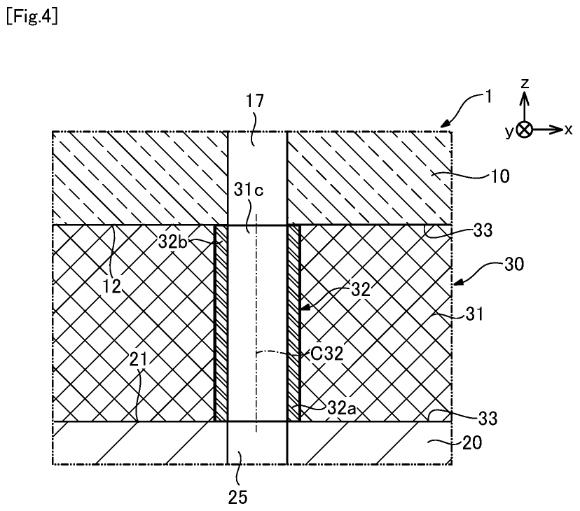

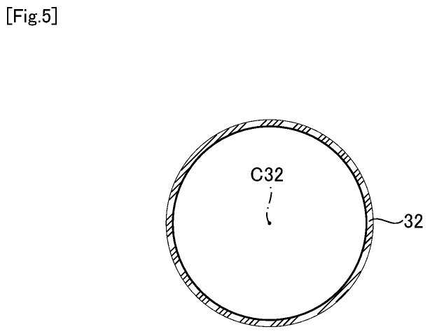

FIG. 4 is a first view used for explaining the tubular member 32 and is an enlarged view of a portion A of FIG. 3. FIG. 5 is a second view used for explaining the tubular member 32 and is a sectional view of the tubular member 32, taken perpendicular to an axis C32. The tubular member 32 has two end portions 32a and 32b. One end portion 32a is in contact with the one main face 21 of the metal member 20, and the other end portion 32b is in contact with the other main face 12 of the ceramic member 10. In the present embodiment, the one end portion 32a is joined to the one main face 21 of the metal member 20 by an unillustrated brazing filler metal, and the other end portion 32b is joined to the other main face 12 of the ceramic member 10 by an unillustrated brazing filler metal. In the present embodiment, the cross section of the tubular member 32 taken perpendicular to the direction of the axis C32 is circular (see FIG. 5).

The tubular member 32 disposed in the through hole 31a restricts movement of fluid between an inner side portion of the through hole 31a and an interior portion of the metal layer 31. As a result, a processing gas or the like which resides on the outer side of the electrostatic chuck 1 when the wafer W is processed in the etching apparatus becomes less likely to flow into the through holes 23 and 31a and the recess 14 via the metal layer 31. Also, a fragment of the metal fibers which form the metal layer 31 is prevented from falling into the through hole 31a.

The tubular member 32 disposed in the through hole 31c restricts movement of fluid between an inner side portion of the through hole 31c and an interior portion of the metal layer 31. As a result, the helium gas flowing through the through hole 25 of the metal member 20, the through hole 31c of the metal layer 31, and the through hole 17 of the ceramic member 10 is prevented from leaking into an interior portion of the metal layer 31. Also, a fragment of the metal fibers of the metal layer 31 is prevented from falling into the through hole 31c.

The brazing filler metal 33 is a silver (Ag)-based brazing filler metal. The brazing filler metal 33 adheres to the other main face 12 of the ceramic member 10 and the one main face 21 of the metal member 20 while infiltrating into the plurality of pores of the metal layer 31. Notably, the brazing filler metal 33 may be a filler material (e.g., titanium (Ti)-containing brazing filler metal or solder), adhesive (e.g., silicone resin, acrylic resin, or epoxy resin), or inorganic adhesive (e.g., glass paste).

Next, a method for manufacturing the electrostatic chuck 1 will be described. In the method for manufacturing the electrostatic chuck 1, first, a metal foil (hereinafter referred to as the “metal member-side metal foil”), which becomes the brazing filler metal 33, is disposed on the one main face 21 of the metal member 20 having the through holes 23, 24, and 25 and the coolant passage 200 formed therein. Next, the metal layer 31 having the through holes 31a, 31b, and 31c formed therein is disposed on the metal member-side metal foil, and the tubular members 32 are inserted into the through holes 31a and 31c, respectively. Next, another metal foil (hereinafter referred to as the “ceramic member-side metal foil”), which becomes the brazing filler metal 33, is disposed on the side of the metal layer 31 opposite the metal member 20. The ceramic member 10 is disposed on the ceramic member-side metal foil. Subsequently, the ceramic member 10 and the metal layer 31 are joined together by using the ceramic member-side metal foil, and the metal member 20 and the metal layer 31 are joined together by using the metal member-side metal foil. As a result, the joined body la is completed. The electrode terminal 15 and the lift pin 18 are incorporated into the completed joined body 1a, whereby the electrostatic chuck 1 is completed.

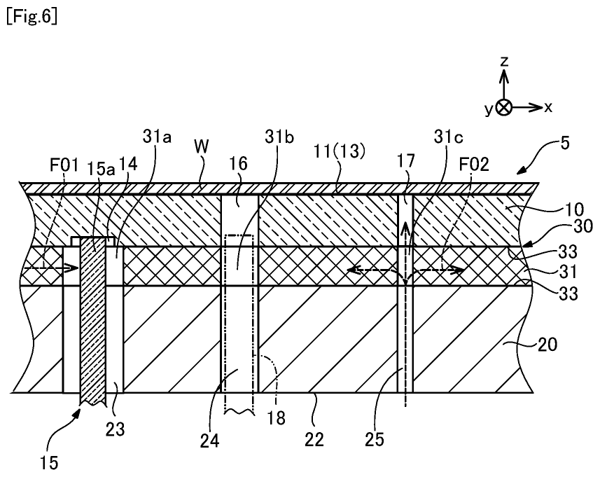

FIG. 6 is a sectional view of an electrostatic chuck 5 of a comparative example. Next, the effect of the tubular members 32 in the electrostatic chuck 1 of the present embodiment will be described while comparing with the electrostatic chuck 5 of the comparative example. In the electrostatic chuck 5 of the comparative example, no tubular member is disposed in the through holes 31a and 31c of the joining portion 30.

When a wafer W is plasma-processed by using the electrostatic chuck 5 of the comparative example, a processing gas resides around the electrostatic chuck 5. There is a possibility that this processing gas flows into the through hole 31a through a plurality of pores formed in the metal layer 31 (see a broken line arrow F01 of FIG. 6). Also, there is a possibility that, as a result of the inflow of the processing gas at that time, a fragment of the metal fibers of the metal layer 31 falls into the through hole 31a.

In the case of the electrostatic chuck 5 of the comparative example, when the wafer W is processed, helium gas is suppled between the placement surface 13 and the wafer W via the through hole 25 of the metal member 20, the through hole 31c of the joining portion 30, and the through hole 17 of the ceramic member 10. In the electrostatic chuck 5 of the comparative example, since the helium gas flowing through the through hole 31c of the joining portion 30 leaks from the through hole 31c into a plurality of pores of the metal layer 31 (see broken line arrows F02 of FIG. 6), there is a possibility that the flow rate of the helium gas flowing through the through hole 31c decreases, which makes it difficult to stably supply the helium gas between the placement surface 13 and the wafer W. Also, there is a possibility that the remaining gas within the joining portion 30 flows into the through hole 31c and contaminates the wafer W. Furthermore, there is a possibility that a fragment of the metal fibers of the metal layer 31 having fallen into the through hole 31c as a result of the inflow of the remaining gas moves to the placement surface 13 together with the helium gas and adheres to the wafer W, whereby the wafer W is contaminated.

In the electrostatic chuck 1 of the present embodiment, the tubular member 32 is disposed in the through hole 31a of the joining portion 30 (see FIG. 3). Since the processing gas residing around the electrostatic chuck 1 is blocked by the tubular member 32 disposed in the through hole 31a, the processing gas becomes less likely to flow into the through holes 23 and 31a and the recess 14 (see a broken line arrow F11 of FIG. 3). Also, the tubular member 32 prevents a fragment of the metal fibers of the metal layer 31 from entering the through holes 23 and 31a and the recess 14.

In the electrostatic chuck 1 of the present embodiment, the tubular member 32 is disposed in the through hole 31c of the joining portion 30 (see FIG. 3). As a result, the helium gas flowing through the through hole 31c of the joining portion 30 is stably supplied between the placement surface 13 and the wafer W without leaking from the through hole 31c to an interior portion of the metal layer 31 (see a broken line arrow F12 of FIG. 3). Therefore, the helium gas atmosphere between the placement surface 13 and the wafer W can be stabilized. Also, since the remaining gas in the joining portion 30 is prevented from flowing into the through hole 31c, contamination of the wafer W is prevented. Furthermore, since it is possible to prevent falling of a fragment of the metal fibers of the metal layer 31 into the through hole 31c, which falling would otherwise occur as a result of inflow of the remaining gas of the joining portion 30, contamination of the wafer W by the fragment is prevented.

According to the above-described joined body la of the the present embodiment, the metal layer 31 contained in the joining portion 30 has a plurality of pores communicating with each other, and the through holes 31a and 31c communicating with the through holes 23 and 25, respectively, of the metal member 20 are formed in the metal layer 31. The tubular members 32 are disposed in the through holes 31a and 31c, respectively, of the metal layer 31 so as to restrict movement of gases between the respective inner side portions of the through holes 31a and 31c and interior portions of the metal layer 31. As a result, the tubular member 32 disposed in the through hole 31a can prevent a fragment of the metal fibers of the metal layer 31 from falling into the through hole 31a, while preventing the processing gas for the wafer W from flowing into the through hole 31a. Also, the tubular member 32 disposed in the through hole 31c can prevent a fragment of the metal fibers of the metal layer 31 from falling into the through hole 31c, while preventing the helium gas flowing through the through hole 31c from leaking to an interior portion of the metal layer 31.

Also, according to the joined body la of the present embodiment, the through holes 25 and 31c formed in the metal member 20 and the metal layer 31, respectively, communicate with the through hole 17 formed in the ceramic member 10. In the through hole 31c formed in the metal layer 31, the helium gas flowing through the through hole 31c is prevented from leaking to the metal layer 31, and the fluid present in the metal layer 31 is prevented from flowing into an inner side portion of the through hole 31c. Therefore, a change in the flow rate of the helium gas flowing through the through hole 17 of the ceramic member 10 relative to the flow rate of the helium gas flowing through the through hole 25 of the metal member 20 becomes small. As a result, the helium gas can be stably supplied from the metal member 20 side to the ceramic member 10 side via the joined body 1a, whereby the helium gas can be stably supplied between the wafer W and the placement surface 13.

Also, according to the joined body la of the present embodiment, the tubular members 32 are formed of the same material as the metal layer 31. As a result, the joining portion 30 is formed of two types of materials; i.e., the material of the metal layer 31 and the tubular members 32 and the material of the brazing filler metal 33. Therefore, the composition of the joining portion 30 becomes uniform throughout the joining portion as compared with the case where the brazing filer metal, the metal layer, and the tubular members are formed of different materials. Accordingly, local differences in thermal stress become less likely to be produced in the joining portion 30, whereby breakage of the joined body 1a can be prevented.

Also, according to the joined body 1a of the present embodiment, each of the tubular members 32 is formed such that a cross section perpendicular to the direction of the axis C32 becomes circular as shown in FIG. 5. As a result, the tubular members 32 become less likely to deform due to forces acting from directions intersecting the axis C32. Therefore, it is possible to further reliably prevent movement of fluids between the through holes 31a and 31c and the metal layer 31 and falling of fragments of the metal layer 31 into the through holes 31a and 31c.

Also, according to the electrostatic chuck 1 of the present embodiment, for example, the through holes 25 and 31c formed in the metal member 20 and the metal layer 31, respectively, communicate with the through hole 17 of the ceramic member 10, and a change in the flow rate of the helium gas flowing through the through hole 31c is prevented. Therefore, the helium gas can be stably supplied between the wafer W and the placement surface 13. Also, since falling of a fragment of the metal layer 31 into the through hole 31c is prevented, contamination of the wafer W by the fragment of the metal layer 31 can be prevented. As a result, the yield of products can be improved.

### 2. Second Embodiment

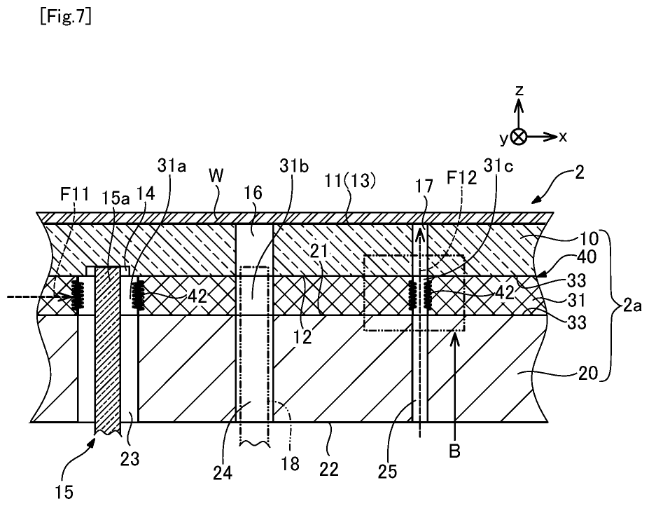

FIG. 7 is a sectional view of an electrostatic chuck 2 of a second embodiment. In the electrostatic chuck 2 of the second embodiment, tubular members have a shape different from the shape of the tubular members of the electrostatic chuck 1 of the first embodiment (FIG. 3).

The electrostatic chuck 2 of the present embodiment includes the ceramic member 10, the electrode terminal 15, the lift pin 18, the metal member 20, and a joining portion 40. The joining portion 40, which joins the ceramic member 10 and the metal member 20 together, includes the metal layer 31, tubular members 42, and the brazing filler metal 33. In the electrostatic chuck 2, a joined body 2a composed of the ceramic member 10, the joining portion 40, and the metal member 20 is an approximately circular columnar body.

Each of the tubular members 42 is an approximately cylindrical member which is open upward and downward and has a sealed side wall. As shown in FIG. 7, the tubular members 42 are disposed in the through hole 31a and the through hole 31c, respectively. The tubular member 42 disposed in the through hole 31a prevents a fragment of the metal fibers of the metal layer 31 from falling into the through hole 31a, while preventing the processing gas for the wafer W from flowing into the through hole 31a. The tubular member 42 disposed in the through hole 31c prevents a fragment of the metal fibers of the metal layer 31 from falling into the through hole 31c, while preventing the helium gas flowing through the through hole 31c from leaking to an interior portion of the metal layer 31.

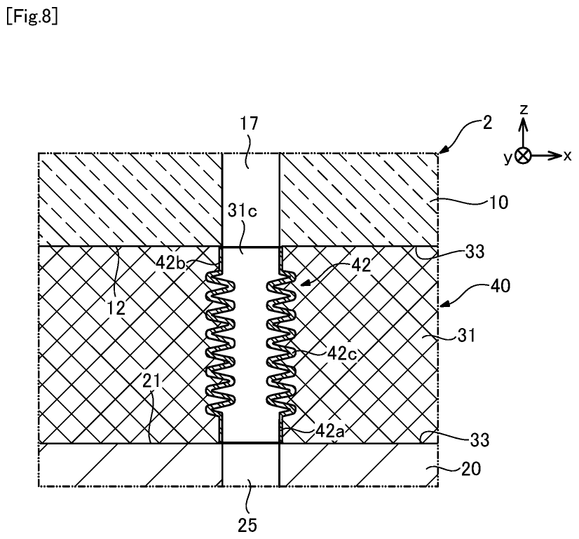

FIG. 8 is an enlarged sectional view of the electrostatic chuck 2; specifically, an enlarged view of a portion B of FIG. 7. Each tubular member 42 has two end portions 42a and 42b and a bellows portion 42c which connects the two end portions 42a and 42b. One end portion 42a is located on the z-axis direction negative side of the tubular member 42 and is in contact with the one main face 21 of the metal member 20, and the other end portion 42b is located on the z-axis direction positive side of the tubular member 42 and is in contact with the other main face 12 of the ceramic member 10. The bellows portion 42c is formed along the circumference of the tubular member 42 to extend in the circumferential direction. The bellows portion 42c deforms in accordance with the relation between the position of the one end portion 42a and the position of the other end portion 42b.

According to the above-described electrostatic chuck 2 of the present embodiment, the bellows portion 42c is formed along the circumference of the tubular member 42 to extend in the circumferential direction. As a result, for example, when the ceramic member 10 and the metal member 20 are joined together or when the electrostatic chuck 2 is used at high temperature, the bellows portion 42c deforms in accordance with the magnitude of stress generated due to the difference in thermal expansion between the ceramic member 10 and the metal member 20. When the bellows portion 42c deforms, it is possible relax the residual stress at the junction interface between the ceramic member 10 and the metal member 20 and the residual stress of the ceramic member 10, which is relatively weak against stress. Accordingly, breakage of the electrostatic chuck 2 can be prevented.

### 3. Third Embodiment

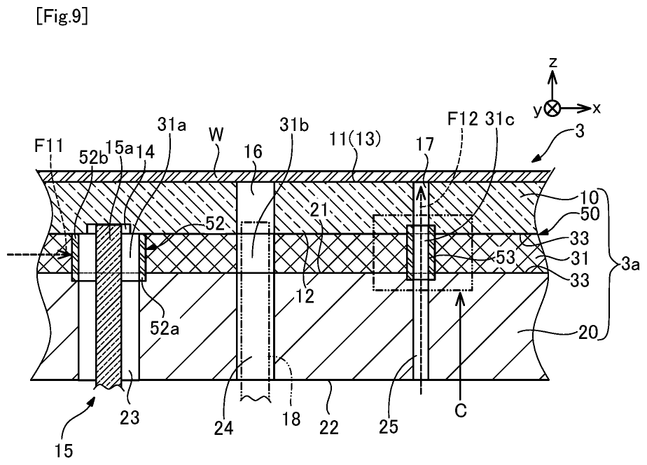

FIG. 9 is a partial sectional view of an electrostatic chuck 3 of a third embodiment. In the electrostatic chuck 3 of the third embodiment, the end portions of the tubular members are located at positions different from the positions of the end portions of the tubular members of the electrostatic chuck 1 of the first embodiment (FIG. 3).

The electrostatic chuck 3 of the present embodiment includes the ceramic member 10, the electrode terminal 15, the lift pin 18, the metal member 20, and a joining portion 50. The joining portion 50, which joins the ceramic member 10 and the metal member 20 together, includes the metal layer 31, tubular members 52 and 53, and the brazing filler metal 33. In the electrostatic chuck 3, a joined body 3a composed of the ceramic member 10, the joining portion 50, and the metal member 20 is an approximately circular columnar body.

The tubular member 52 is a cylindrical member which is open upward and downward and has a sealed side wall. The tubular member 52 is disposed in the through hole 31a of the metal layer 31. As shown in FIG. 9, of two end portions 52a and 52b of the tubular member 52, one end portion 52a is disposed in the through hole 23 of the metal member 20. The other end portion 52b is in contact with the other main face 12 of the ceramic member 10. As a result, a gap is less likely to be formed between the metal member 20 and the tubular member 52. Therefore, the processing gas for the wafer W is prevented from flowing into the through hole 31a, and a fragment of the metal fibers of the metal layer 31 is prevented from falling into the through hole 31a. Notably, the other end portion 52b of the tubular member 52 may be disposed in a groove or the like formed on the other main face 12 of the ceramic member 10.

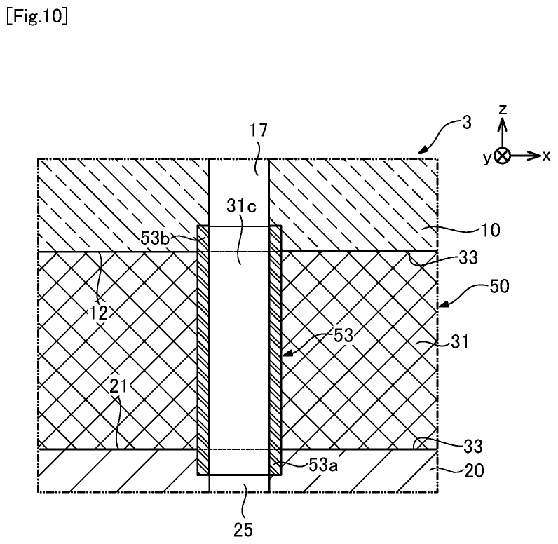

FIG. 10 is an enlarged sectional view of the electrostatic chuck 3; specifically, an enlarged view of a portion C of FIG. 9. The tubular member 53 is a cylindrical member which is open upward and downward and has a sealed side wall. The tubular member 53 is disposed in the through hole 31c of the metal layer 31. Of two end portions 53a and 53b of the tubular member 53, one end portion 53a is disposed in the through hole 25 of the metal member 20. The other end portion 53b is disposed in the through hole 17 of the ceramic member 10. As a result, a gap is unlikely to be formed between the ceramic member 10 and the tubular member 53 and between the metal member 20 and the tubular member 53. Therefore, the helium gas flowing through the through hole 31c is prevented from leaking to an interior portion of the metal layer 31, and a fragment of the metal fibers of the metal layer 31 is prevented from falling into the through hole 31c.

According to the above-described electrostatic chuck 3 of the present embodiment, the one end portion 52a of the tubular member 52 is disposed in the through hole 23 of the metal member 20. The one end portion 53a of the tubular member 53 is disposed in the through hole 25 of the metal member 20, and the other end portion 53b of the tubular member 53 is disposed in the through hole 17 of the ceramic member 10. As a result, it is possible to prevent separation of the tubular members 52 and 53 from the ceramic member 10 and the metal member 20, which separation would otherwise occur due to thermal stress generated in the electrostatic chuck 3 when the ceramic member 10 and the metal member 20 are joined together by the joining portion 50 or when the electrostatic chuck 3 is used at high temperature. Accordingly, it is possible to further reliably prevent falling of a fragment of the metal layer 31 into the through hole 31c, while further restricting movement of fluid between an inner side portion of the through hole 31c and an interior portion of the metal layer 31.

### 4. Modifications of the Present Embodiments

The present invention is not limited to the above-described embodiments and can be practiced in various forms without departing from the gist of the invention, and, for example, the following modifications are possible.

### A. Modification 1

In the above-described embodiments, the “joined body” includes the ceramic member 10 and the metal member 20. However, the combination of members which constitute the “joined body” is not limited thereto. For example, the joined body may be a joined body in which ceramic members are joined together or a joined body in which metal members are joined together. Further, the joined body may be formed by using materials other than ceramic materials and metals. For example, the joined body may be formed by using glass, glass epoxy, resin (e.g., thermoplastic resin, thermosetting resin, etc.), paper phenol, paper epoxy, glass composite, and a metal member with any of these insulating members formed on the surface.

### B. Modification 2

In the above-described embodiments, the ceramic member 10 has the recess 14 which communicates with the through hole 31a of the joining portion 30 and the through hole 17 which communicates with the through hole 31c and which serves as the “through hole of the second member.” However, either of the “through hole” and the recess communicating with the through hole of the joining portion may be formed in the “second member.” Also, the through hole and the recess may be omitted or a plurality of through holes may be formed.

### C. Modification 3

In the above-described embodiments, the tubular members are formed of a metal containing titanium, which is the same material as the metal layer. However, the material used to form the tubular members may differ from the material used to form the metal layer, and is not limited to the metal containing titanium. The material used to form the tubular members may be a metal other than titanium or a ceramic material such as alumina or aluminum nitride. The tubular members are desirably dense bodies. In the case where the tubular members and the metal layer are formed of the same material, since the composition of the joining portion becomes uniform throughout the joining portion, local differences in thermal stress become less likely to be produced in the joining portion, whereby breakage of the joined body can be prevented.

### D. Modification 4

In the above-described embodiments, each tubular member has a circular cross section taken perpendicular to the axial direction of the tubular member. However, the cross section of the tubular member perpendicular to the axial direction may be non-circular.

### E. Modification 5

In the above-described embodiments, the electrostatic chuck is provided in an etching apparatus. However, the field of application of the electrostatic chuck is not limited thereto. For example, the electrostatic chuck may be an electrostatic chuck equipped with a heater for heating a wafer. In the case where the electrostatic chuck has a heater, since the electrostatic chuck is used under a high temperature environment, it is desired that the tubular members be formed of a metal having a high heat proof temperature. Also, the electrostatic chuck may be used to, for example, fix, correct, or transfer a wafer in a semiconductor manufacturing apparatus. Furthermore, the “holding apparatus” including the joined body is not limited to the electrostatic chuck and may be used as a placement table, a susceptor, or a heater for a vacuum apparatus such as a CVD (Chemical Vapor Deposition) apparatus, a PVD (Physical Vapor Deposition) apparatus, a PLD (Pulsed Laser Deposition) apparatus or the like. Accordingly, the force for holding an object to be held is not limited to electrostatic attraction force.

### F. Modification 6

In the above-described embodiments, each joined body may include an additional layer such as a metal layer between the ceramic member and the joining portion and/or between the metal member and the joining portion. This additional layer may be, for example, a layer formed as a result of vaporization of titanium in the brazing filler metal which forms the joining portion, or a metallization layer formed beforehand.

### G. Modification 7

In the above-described embodiments, each of the joined bodies 1a, 2a, and 3a each of which includes the ceramic member 10, the joining portion 30, 40, or 50, and the metal member 20 has an approximately circular columnar shape. However, the shape of the “joined body” is not limited thereto. For example, the joined body may have a rectangular shape, a polygonal shape, etc.

### H. Modification 8

In the third embodiment, the one end portion 52a of the tubular member 52 disposed around the electrode terminal 15 is disposed in the through hole 23 on the side toward the one main face 21 of the metal member 20. However, no limitation is imposed on the position where the end portion of the tubular member is disposed.

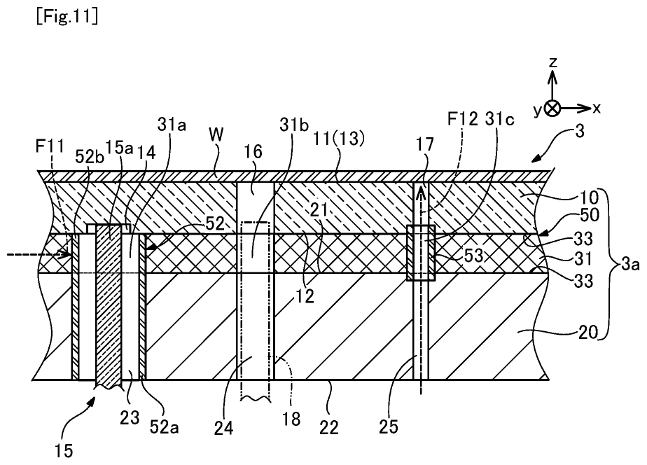

FIG. 11 is a sectional view of a modification of the electrostatic chuck 3 of the third embodiment. As shown in FIG. 11, the one end portion 52a of the tubular member 52 is disposed in the through hole 25 on the side toward the other main face 22 of the metal member 20. Namely, the tubular member 52 may be disposed to penetrate the metal member 20. Also, in the third embodiment, the tubular member 53 may be disposed to penetrate the ceramic member 10 and/or the metal member 20.

### I. Modification 9

In the third embodiment, the one end portion 52a of the tubular member 52 is disposed in the through hole 23 of the metal member 20, and the other end portion 52b is in contact with the other main face 12 of the ceramic member 10. It is sufficient that, as described above, one of the two end portions of each tubular member of the joining portion is disposed in any one of the through holes of a member located adjacent to the joining portion. By virtue of this configuration, the tubular member is prevented from separating from the member having the through hole into which the end portion of the tubular member is inserted.

Therefore, it is possible to further reliably prevent a fragment of the metal layer from falling into the through hole, while further restricting movement of fluids between the inner side portion of the through hole of the metal layer and the interior portion of the metal layer.

Although the present aspects have been described on the basis of embodiments and modifications, the above-described embodiments of the aspects are provided so as to facilitate the understanding of the present aspects and do not limit the present aspects. The present aspects can be changed or improved without departing from the purpose of the aspects and the claims, and encompass equivalents thereof. Also, the technical feature(s) may be eliminated as appropriate unless the present specification mentions that the technical feature(s) is mandatory.

### DESCRIPTION OF REFERENCE CHARACTERS

1, 2, 3: electrostatic chuck
1a, 2a, 3a: joined body
10: ceramic member
13: placement surface
16, 17: through hole (of the ceramic member)
20: metal member
23, 24, 25: through hole (of the metal member)
30, 40, 50: joining portion
31: metal layer
31a, 31c: through hole
32, 42, 52, 53: tubular member
32a, 42a, 52a, 53a: one end portion
32b, 42b, 52b, 53b: the other end portion
42c: bellows portion W: wafer

What is claimed is:

1. A joined body in which a first member and a second member are joined together via a joining portion including a metal layer having a plurality of pores communicating with each other, wherein
the first member and the metal layer have respective through holes formed in the first member and the metal layer, respectively, and communicating with each other, and
a tubular member is disposed between an inner side portion of the through hole formed in the metal layer and an interior portion of the metal layer.

2. The joined body according to claim 1, wherein
a through hole communicating with the through holes formed in the first member and the metal layer, respectively, is formed in the second member.

3. The joined body according to claim 2, wherein
one end portion of the tubular member is disposed in the through hole formed in the first member, and the other end portion of the tubular member is disposed in the through hole formed in the second member.

4. The joined body according to claim 1, wherein
a bellows portion is formed along a circumference of the tubular member to extend in a circumferential direction.

5. The joined body according to claim 1, wherein
the tubular member is formed of the same material as the metal layer.

6. The joined body according to claim 1, wherein
the tubular member has a circular cross section taken perpendicular to an axial direction of the tubular member.

7. A holding apparatus comprising the joined body according to claim 1, wherein
the second member has a placement surface on which an object to be held is placed.

8. An electrostatic chuck comprising the holding apparatus according to claim 7, wherein
the second member has an electrostatic attraction electrode disposed therein.

9. The joined body according to claim 2, wherein
a bellows portion is formed along a circumference of the tubular member to extend in a circumferential direction.

10. The joined body according to claim 3, wherein
a bellows portion is formed along a circumference of the tubular member to extend in a circumferential direction.

11. The joined body according to claim 2, wherein
the tubular member is formed of the same material as the metal layer.

12. The joined body according to claim 3, wherein
the tubular member is formed of the same material as the metal layer.

13. The joined body according to claim 4, wherein
the tubular member is formed of the same material as the metal layer.

14. The joined body according to claim 2, wherein
the tubular member has a circular cross section taken perpendicular to an axial direction of the tubular member.

15. The joined body according to claim 3, wherein
the tubular member has a circular cross section taken perpendicular to an axial direction of the tubular member.

16. The joined body according to claim 4, wherein
the tubular member has a circular cross section taken perpendicular to an axial direction of the tubular member.

17. The joined body according to claim 5, wherein
the tubular member has a circular cross section taken perpendicular to an axial direction of the tubular member.

18. A holding apparatus comprising the joined body according to claim 2, wherein
the second member has a placement surface on which an object to be held is placed.

19. A holding apparatus comprising the joined body according to claim 3, wherein
the second member has a placement surface on which an object to be held is placed.

20. A holding apparatus comprising the joined body according to claim 4, wherein
the second member has a placement surface on which an object to be held is placed.
